(19) United States
(12) Patent Application Publication
(10) Pub. No.: US 2015/0235804 A1
(43) Pub. Date: Aug. 20, 2015

(54) Charged Particle Microscope System and Measurement Method Using Same

(71) Applicant: Hitachi High-Technologies Corporation, Minato-ku, Tokyo (JP)

(72) Inventors: Mayuka Osaki, Tokyo (JP); Maki Kimura, Tokyo (JP); Chie Shishido, Tokyo (JP); Katsuhiro Sasada, Tokyo (JP)

(21) Appl. No.: 14/421,163

(22) PCT Filed: Aug. 7, 2013
(86) PCT No.: PCT/JP2013/071315

§ 371 Date: Feb. 12, 2015

(30) Foreign Application Priority Data
Sep. 19, 2012 (JP) 2012-205227

(51) Int. Cl. H01J 37/22; G02B 21/00; G06T 5/00

(52) U.S. Cl. CPC H01J 37/222; G06T 5/001; G02B 21/008; G06T 2207/10061; H01J 2237/221

(57) ABSTRACT

A charged particle microscope system with a charged particle microscope including an irradiation unit that irradiates a subject to be inspected with a charged particle beam and a detection unit having a detector that detects a charged particle signal from the subject to be inspected irradiated by the irradiation unit; a signal processing unit that converts the charged particle signal detected by the detector of the charged particle microscope into an image signal; and an arithmetic processing unit that corrects the image signal converted by the signal processing unit with the use of signal conversion characteristics.

### TECHNICAL FIELD

The present invention relates to a charged particle microscope system and a measurement method using the same.

### BACKGROUND ART

Background art in this technical field is disclosed in JP 2000-67797 A (PTL 1). PTL 1 describes that image quality obtained by a plurality of detection optical systems relative to one kind of input signal is quantitatively evaluated, and the evaluation results are used to adjust image processing parameters for inspection such that the detection optical systems are equivalent in inspection sensitivity.

### CITATION LIST

### Patent Literature

PTL 1: JP 2000-67797 A

### SUMMARY OF INVENTION

### Technical Problem

PTL 1 discloses a technique by which image quality obtained by a plurality of detection optical systems relative to one kind of input signal is quantitatively evaluated, and the evaluation results are used to adjust image processing parameters for inspection such that the detection optical systems are equivalent in inspection sensitivity. However, PTL 1 does not disclose a relationship between an input signal and an output signal in a certain range is quantitatively evaluated between the plurality of detection optical systems.

According to the technique disclosed in PTL 1 relating to inspection devices, the evaluation of an output signal relative to one specific input signal is considered as effective. However, if the technique is applied to measurement devices in which signal waveform information obtained from a subject to be imaged by a charged particle microscope is used to measure the dimensions of the subject to be imaged, it is important that the relationship between an input signal and an output signal in a certain range is equivalent between the devices.

In addition, if, regardless of the magnitude of the input signal, there are certain differences in magnitude of the output signal between the plurality of detection optical systems or the plurality of devices, the method described in PTL 1 is effective. In actuality, however, the differences in magnitude of the output signal between the plurality of detection optical systems or the plurality of devices depend on the magnitude of the input signal.

### Solution to Problem

To solve the foregoing problem, a configuration described in the claims is utilized, for example. The present invention includes a plurality of means for solving the foregoing problem. As an example, one of the means is a charged particle microscope system including: a charged particle microscope including an irradiation unit that irradiates a subject to be inspected with a charged particle beam and a detection unit that detects a charged particle signal from the subject to be inspected irradiated by the irradiation unit; a signal processing unit that converts the charged particle signal detected by the detector of the charged particle microscope into an image signal; and an arithmetic processing unit that corrects the image signal converted by the signal processing unit with the use of signal conversion characteristics.

### Advantageous Effects of Invention

According to the present invention, it is possible to provide a charged particle microscope having the function of correcting differences in signal amount between devices and a measurement method using the same.

Problems, configurations, and advantages other than the foregoing ones will be more clarified by the following descriptions of embodiments.

### BRIEF DESCRIPTION OF DRAWINGS

FIG. 1 illustrates an example of a configuration diagram of a scanning electron microscope system according to the present invention.

FIG. 2 illustrates an example of signal conversion characteristics in the scanning electron microscope system according to the present invention.

FIG. 3 illustrates an example of a difference in signal conversion characteristics between devices in the scanning electron microscope system.

FIG. 4 illustrates an example of a difference in output waveform between the devices in the scanning electron microscope system.

FIG. 5 illustrates an example of a flowchart of a data acquisition process for calculating signal conversion characteristics according to the present invention.

FIG. 6 illustrates an example of a flowchart of a process for deciding image acquisition conditions without signal saturation.

FIG. 7 illustrates an example of data for deciding the image acquisition conditions without signal saturation.

FIG. 8 illustrates an example of a flowchart of a signal conversion process on an image for dimension measurement according to the present invention.

FIG. 9 illustrates an example of experimentally acquired signal conversion characteristics in the scanning electron microscope system.

FIG. 10 illustrates an example of a table of input signals corresponding to image signals.

FIG. 11 illustrates an example of a GUI for executing data acquisition for calculating signal conversion characteristics according to the present invention.

FIG. 12 illustrates an example of a GUI for displaying evaluation results of signal conversion characteristics and a signal conversion table in the scanning electron microscope system according to the present invention.

FIG. 13 illustrates an example of a flowchart of a data acquisition process for calculating signal conversion characteristics according to the present invention.

FIG. 14 illustrates an example of a flowchart of a data acquisition process for calculating signal conversion characteristics according to the present invention.

FIG. 15 illustrates an example of a flowchart of a data acquisition process for calculating signal conversion characteristics according to the present invention.

FIG. 16 illustrates an example of a flowchart of a data acquisition process for calculating signal conversion characteristics according to the present invention.

FIG. 17 illustrates an example of a flowchart of a signal conversion process on the image for dimension measurement according to the present invention.

FIG. 18 illustrates an example of a GUI for displaying evaluation results of temporal changes in signal conversion characteristics and the temporal changes in a signal conversion table in the scanning electron microscope system according to the present invention.

FIG. 19 illustrates an example of a flowchart of a data acquisition process for calculating a difference in signal conversion characteristics between devices according to the present invention.

FIG. 20 illustrates an example of a flowchart of a signal conversion process on an image for dimension measurement according to the present invention.

FIG. 21 illustrates an example of experimentally acquired signal conversion characteristics in the scanning electron microscope system.

FIG. 22 illustrates an example of a table of image signals in a reference device corresponding to image signals in an evaluation device according to the present invention.

FIG. 23 illustrates an example of a GUI for displaying evaluation results of differences in signal conversion characteristics between devices and a signal conversion table in the scanning electron microscope system according to the present invention.

### DESCRIPTION OF EMBODIMENTS

### First Embodiment

According to this embodiment, descriptions are hereinafter given as to an example of a scanning electron microscope system for dimension measurement in which non-linearity of an output signal is corrected relative to an input signal in a certain range as a reference in a signal processing unit.

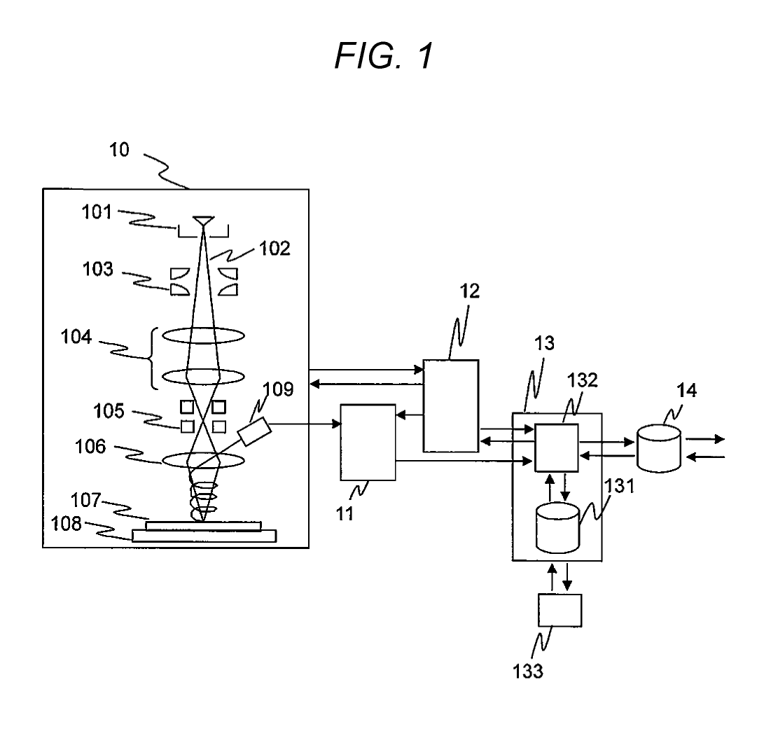

FIG. 1 illustrates an example of a configuration diagram of the scanning electron microscope system in this embodiment.

The scanning electron microscope system in this embodiment is configured to include a scanning electron microscope main body 10, a signal processing unit 11, a general control unit 12, and a PC 13, which are connected to a data server 14 via a network.

The scanning electron microscope main body 10 is configured to include an electron gun 101, acceleration electrodes 103 that accelerate an electron beam 102 emitted from the electron gun 101, focusing lenses 104, deflection electrodes 105 that deflect the trajectory of the electron beam 102, an objective lens 106 that controls the focus position of the electron beam 102 into which the electron beam 102 converges such that the focus position falls on a patterned surface of a sample 107, a table 108 on which the sample 107 is placed, and a detector 109 that detects some of secondary electrons from the sample 107 irradiated with the electron beam 102, which are controlled by the general control unit 12.

A signal detected by the detector 109 is converted into image data at the signal processing unit 11 under instructions from the general control unit 12.

The PC 13 includes a storage unit 131, an arithmetic processing unit 132, and an input/output unit 133 with a display screen.

The arithmetic processing unit 132 in the PC 13 processes the image data converted at the signal processing unit 11 to extract signal conversion characteristics as information related to a relationship between an input signal and an output signal, stores the signal conversion characteristics as extraction results in the storage unit 131, and then displays the same on the display screen. The input signal here refers to a signal detected by the detector 109, and the output signal here refers to a signal processed and output by the signal processing unit 11. The results displayed on the display unit are sent to the data server 14 accessible to a plurality of devices via a communication line, and are stored in the data server 14.

When another image is acquired by imaging, the information related to the relationship between an input signal and an output signal is read from the storage unit 131 of the PC 13 or the data server 14, the other image data is corrected by the arithmetic processing unit 132 based on the read information, the dimensions of the imaged subject are measured, and then the processed image data, the dimension measurement results, the information related to the dimension measurement are stored in the storage unit 131 and displayed on the display screen.

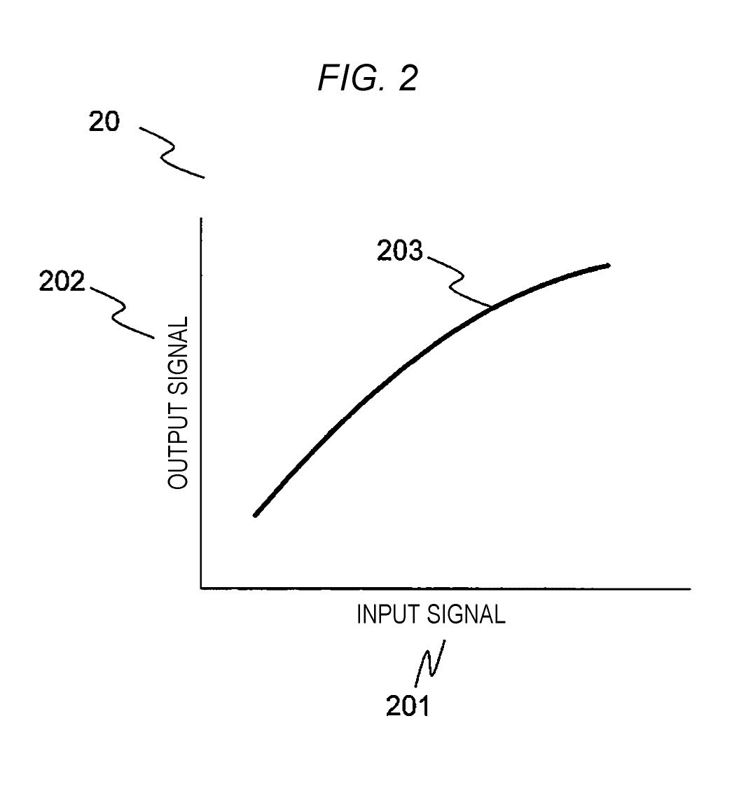

FIG. 2 illustrates an example 20 of a relationship 203 between an input signal 201 and an output signal 202 in a certain range (hereinafter, referred to as signal conversion characteristics) in the scanning electron microscope system illustrated in FIG. 1. The signal of secondary electrons detected by the detector 109 of the scanning electron microscope main body 10 is amplified and biased in the detector 109 and the signal processing unit 11, and then the signal is output as an image to the PC 13.

In general, a signal is acquired with an increased amplification factor such that an output signal does not exceed the upper and lower limits of image gradation, because an output image (corresponding to the output signal) is more favorable in appearance with a higher signal contrast and the impact of a noise signal generated after the amplification of the signal in the detector 109 can be relatively suppressed. Meanwhile, a signal of secondary electrons (corresponding to the input signal) acquired by the detector 109 of the scanning electron microscope main body 10 includes a large proportion of noise relative to the magnitude of the signal. Thus, if the amplification factor of the signal is increased, the signal becomes saturated with the noise content beyond the upper and lower limits of image gradation. Accordingly, the output signal becomes low mainly due to the saturation of the input signal with the noise content. As a result, the relationship 203 between the input signal 201 and the output signal 202 takes on a non-linear form.

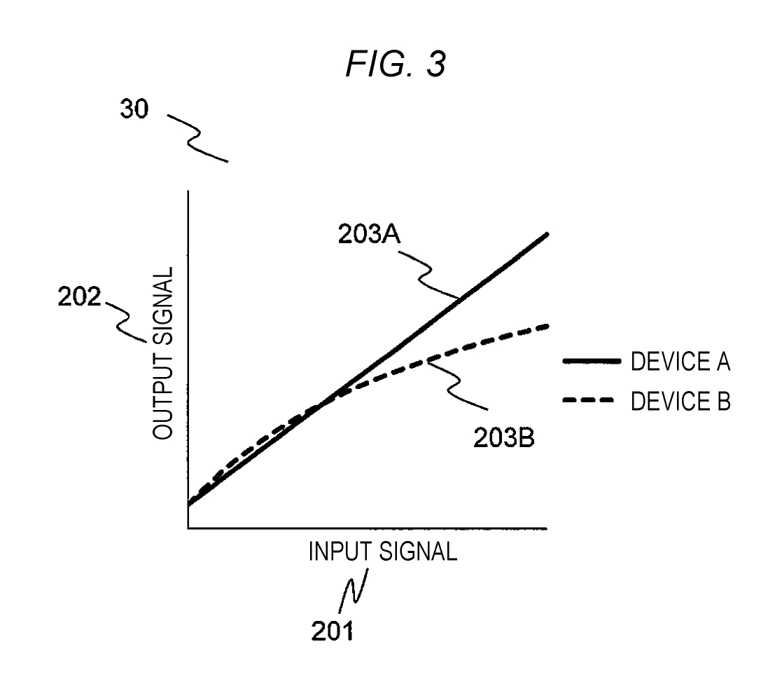

FIG. 3 illustrates an example of a difference in signal conversion characteristics between devices in the scanning electron microscope system. Since the non-linearity varies depending on the magnitude of a noise signal or the like, the tendency of the non-linearity may be different between a plurality of devices as illustrated in FIG. 3. The signal conversion characteristics are represented by the relationship between the input signal 201 and the output signal 202 as illustrated in FIG. 2. It is noted that a signal conversion characteristic 203A in a device A and a signal conversion characteristic 203B in a device B are different from each other.

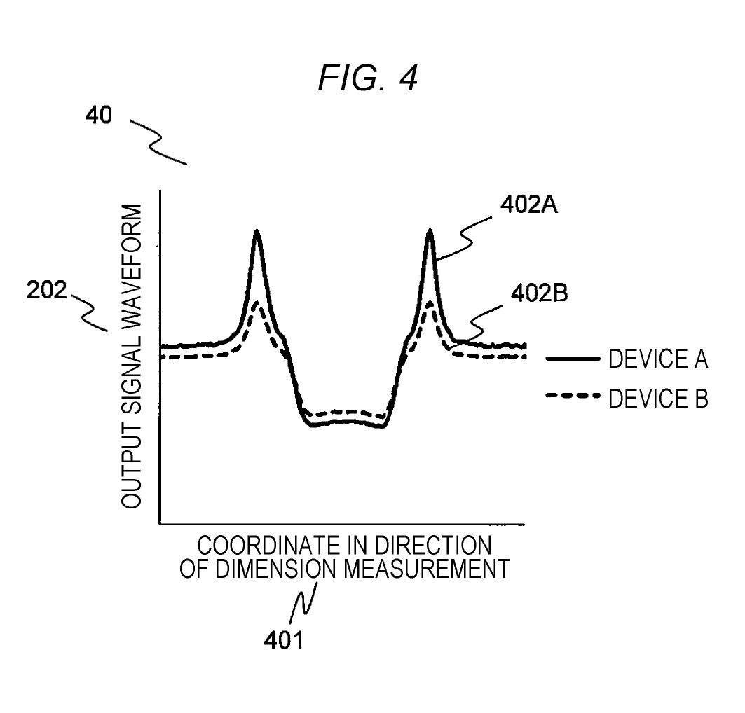

FIG. 4 illustrates an example of a difference in output waveform between the devices in the scanning electron microscope system. As illustrated in FIG. 4, it is noted that output signal waveforms 402A and 402B relative to a coordinate 401 in the direction of dimension measurement acquired by imaging one and the same subject to be measured are different between the devices, which causes a difference in dimension measurement results calculated from the signal waveforms. In this embodiment, it is possible to decrease the difference in signal conversion characteristics between the devices by making corrections at the devices with consideration given to the signal conversion characteristics indicating the non-linearity of the output signal relative to the input signal.

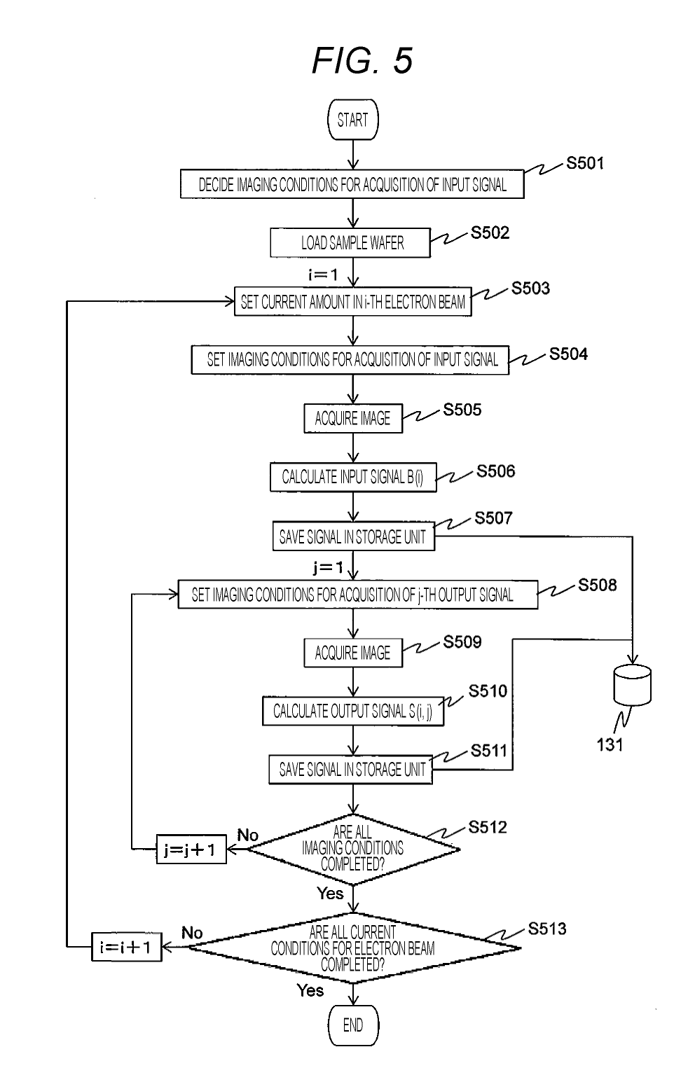

FIG. 5 illustrates a flow of data acquisition for calculating the signal conversion characteristics 20 in the scanning electron microscope system illustrated in FIG. 1. The calculation of the signal conversion characteristics 20 described in FIG. 5 is carried out at the PC 13 including the arithmetic processing unit illustrated in FIG. 1.

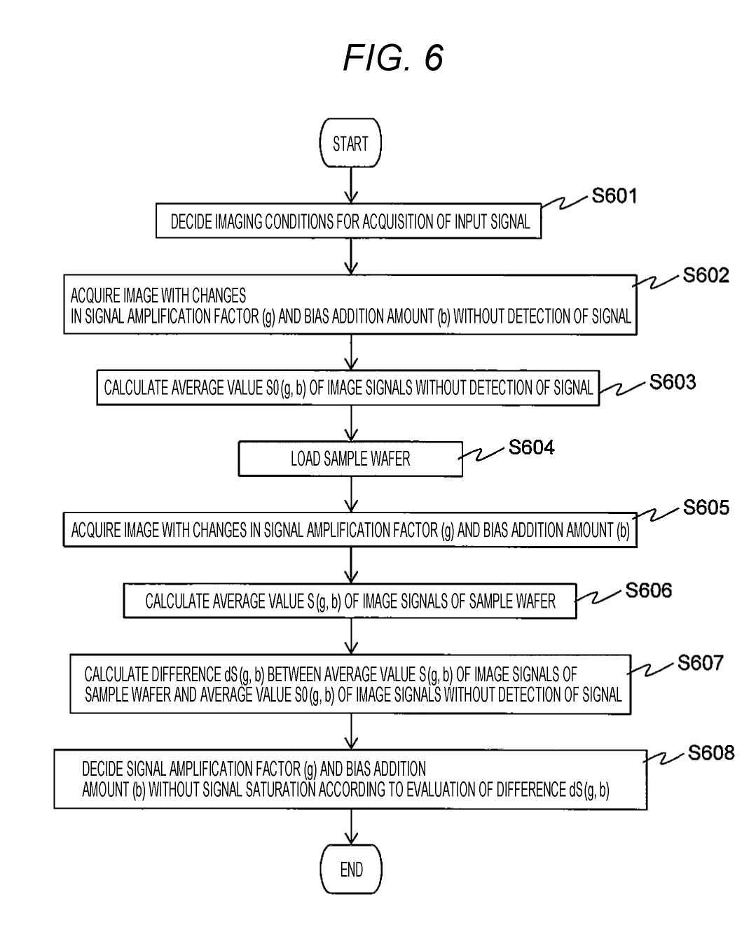

First, image acquisition conditions for acquiring the input signal 201 in a certain range as a reference are decided (S501). This step is needed to, in the case where it is difficult to measure the absolute value of the input signal 201 (the number of secondary electrons detected by the detector 109 in this embodiment) in the scanning electron microscope main body 10, use instead of the input signal 201 an output signal acquired under image acquisition conditions without signal saturation for retention of linearity in a more reliable manner. The flow of deciding the image acquisition conditions without signal saturation will be described later in more detail with reference to FIG. 6. Under the image acquisition conditions without signal saturation, the amplification factor of the signal is lower than that at acquisition of the image for dimension measurement.

When the image acquisition conditions for acquisition of the input signal 201 are decided, a sample wafer for use in acquisition of the input signal 201 and the output signal 202 is loaded onto the table 108 of the scanning electron microscope main body 10 (S502). In this embodiment, a solid film sample of silicon or the like without a pattern or a crystalline pattern on a wafer is used.

Then, the amount of current in the electron beam 102 as one of the image acquisition conditions is set to the i-th value (S503). To obtain the signal conversion characteristics 20 illustrated in FIG. 2, it is necessary to acquire a plurality of input signals 201 and a plurality of output signals 202 corresponding to the input signals 201. In this embodiment, the signals are acquired with changes in the amount of current in the electron beam 102 as a means for changing the magnitude of the input signal 201. The amount of current in the electron beam 102 is desirably changed such that the input signals 201 can be acquired within the range including the input signal acquired from the subject of dimension measurement.

Then, the image acquisition conditions for acquirement of the input signal 201 except for the amount of current in the electron beam 102 are set (S504).

Then, the image is acquired (S505).

Then, the average value of the acquired image signals of a plurality of pixels is calculated and set as an input signal B(i) 201 (S506).

Then, the acquired input signal B(i) 201 is stored in the storage unit 131 (S507).

Then, the image acquisition condition for acquisition of the j-th output signal 202 except for the amount of current in the electron beam 102 is set (S508). The image acquisition condition for acquisition of the output signal 202 is the same as the image acquisition condition for acquisition of the image for dimension measurement. When the image for dimension measurement is to be acquired under a plurality of image acquisition conditions, the output signal 202 is acquired under each of the conditions.

Then, the image is acquired (S509).

Then, the average value of the acquired image signals of a plurality of pixels is calculated and set as an output signal S(i, j) 202 (S510).

Then, the acquired output signal S(i, j) 202 is stored in the storage unit 131 (S511).

The steps S508 to S511 are repeatedly executed until the last number j of the image acquisition condition for acquisition of the output signal 202 is reached (S512).

In addition, the steps S503 to S512 are repeatedly executed until the last number i of the amount of current in the electron beam 102 is reached (S513).

After execution of the foregoing steps, the data acquisition of the input signal B(i) 201 and the output signal S(i, j) 202 with the amount of current i in the electron beam 102 is terminated.

FIG. 6 illustrates a flow of the deciding image acquisition conditions without signal saturation described above in relation to S501 of FIG. 5.

First, imaging conditions for acquisition of the input signal 201 are set (S601).

Then, while the scanning electron microscope main body 10 is set so as not to detect a signal from a sample, images are acquired with changes in signal amplification factor (g) and bias addition amount (b) included in the image acquisition conditions (S602), and the average value of the acquired image signals is calculated (S603). The calculated result is set as S0(g, b). Since there is no signal detected by the detector 109, the signal amount S0(g, b) at that time is ideally represented as in (Equation 1) shown below.

S0(g,b)=g×0+b (Mathematical Formula 1)

Then, a sample wafer to be used in acquisition of data for calculating the signal conversion characteristics 20 is loaded onto the table 108 of the scanning electron microscope main body 10 (S604).

Then, images are acquired under the same conditions of signal amplification factor (g) and bias addition amount (b) as those at S602 (S605), and the average value of the acquired image signals is calculated (S606). The calculated result is set as S(g, b). When the signal detected by the detector 109 is designated as s, the signal amount S(g, b) at that time is ideally represented as in (Mathematical Formula 2) shown below.

S(g,b)=g×s+b (Mathematical Formula 2)

Then, the difference between the signal S(g, b) of the sample wafer acquired with changes in the signal amplification factor (g) and the bias addition amount (b) and the signal S0(g, b) without detection of a signal from the sample is calculated (S607). The calculated result is set as dS(g, b). The signal amount difference dS(g, b) at that time is ideally represented as in (Mathematical Formula 3) shown below according to (Mathematical Formula 1) and (Mathematical Formula 2).

dS(g,b)=g×s (Mathematical Formula 3)

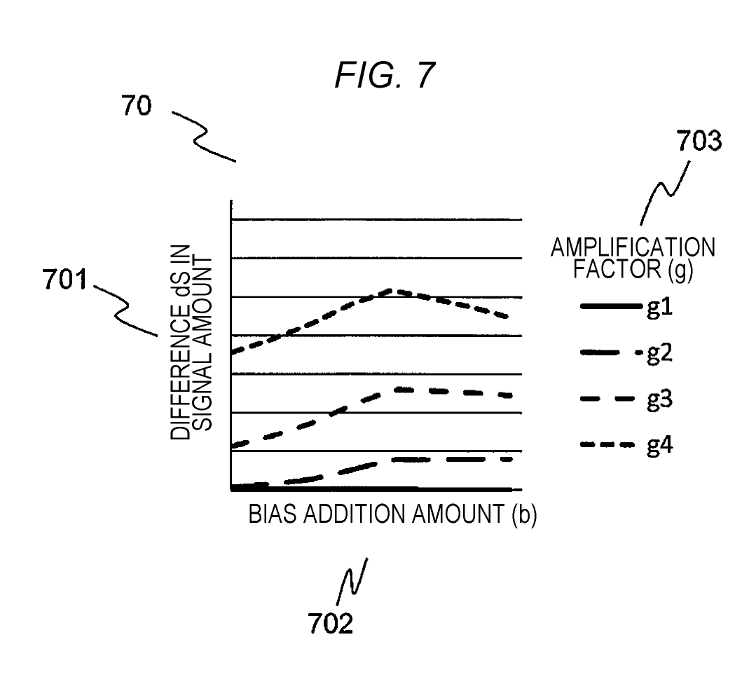

That is, the signal amount difference dS(g, b) ideally takes a constant value without dependence on the bias addition amount (b). In actuality, however, the signal S(g, b) of the sample wafer becomes saturated depending on the conditions of the signal amplification factor (g) and the bias addition amount (b). Thus, as in the example of FIG. 7, the signal amount difference dS(g, b) 701 varies with changes in the bias addition amount (b) 702. FIG. 7 illustrates an example of data for deciding the image acquisition conditions without signal saturation.

Taking these characteristics into account, the conditions of the signal amplifier factor (g) 703 and the bias addition amount (b) 702 are automatically decided such that, even if the bias addition amount (b) 702 varies, the signal does not become saturated while changes in the signal amount difference dS(g, b) 701 are small (S608).

By performing the foregoing steps, the image acquisition conditions without signal saturation are decided.

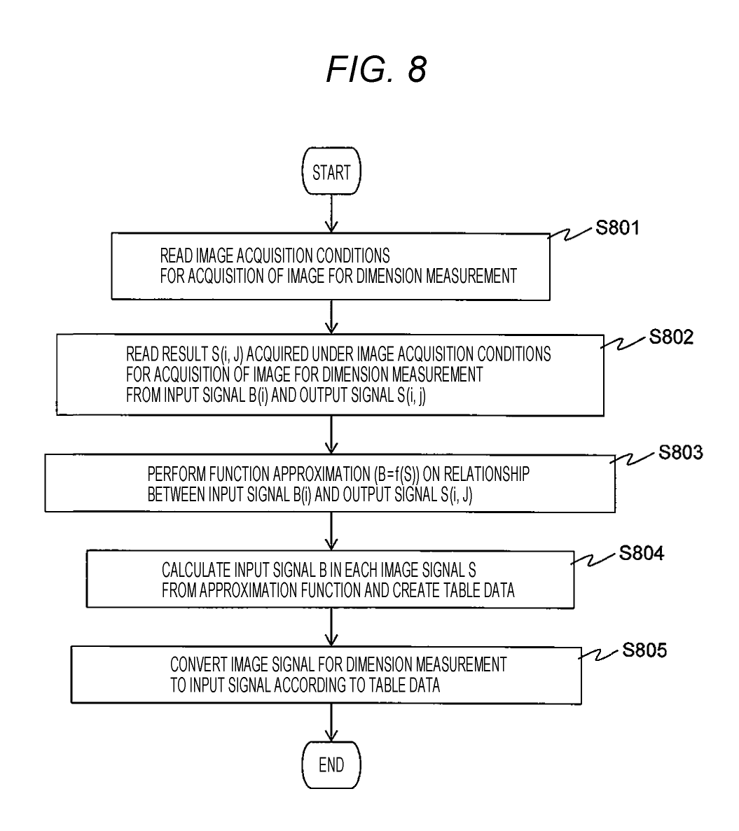

FIG. 8 illustrates a flow of signal conversion in an image for dimension measurement using the data acquired in the flow of data acquisition for calculating the signal conversion characteristics 20 illustrated in FIG. 5.

First, image acquisition conditions for acquisition of the image for dimension measurement are read (S801).

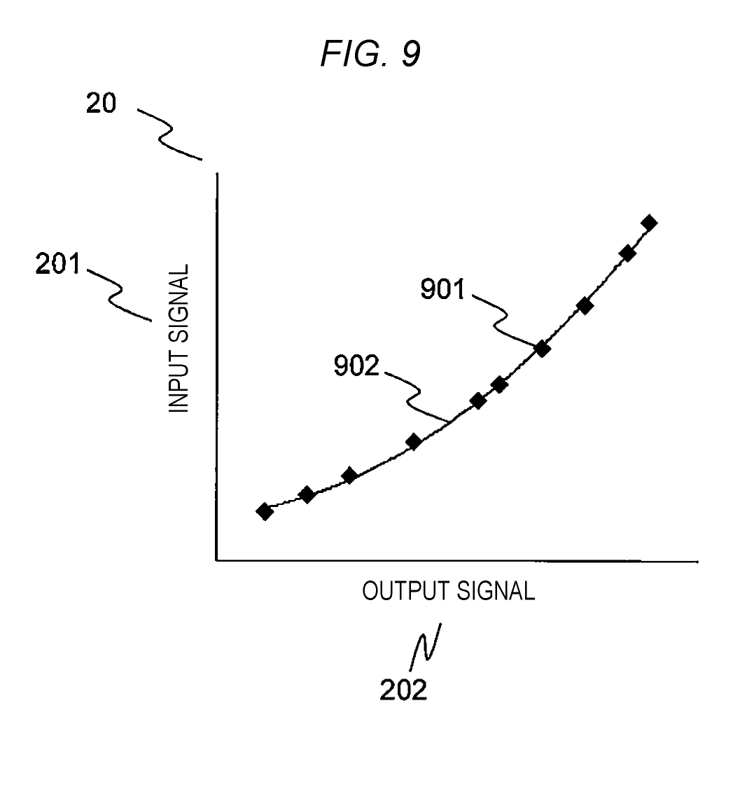

Then, the input signal B(i) 201 or the output signal S (i, j) 202 acquired in the flow of data acquisition (FIG. 5) for calculating the signal conversion characteristics 20 under the target image acquisition condition (j=J) is read (S802). FIG. 9 illustrates a relationship 901 between the input signal B(i) 201 and the output signal S(i, J) 202.

Then, the relationship 901 between the input signal B(i) 201 and the output signal S(i, J) 202 is approximated by a function B=f(S) (S803). The function for use in approximation may be a sigmoid function or a quadratic function, for example. FIG. 9 also illustrates an approximate function 902. The approximate function is adopted as the signal conversion characteristics 20.

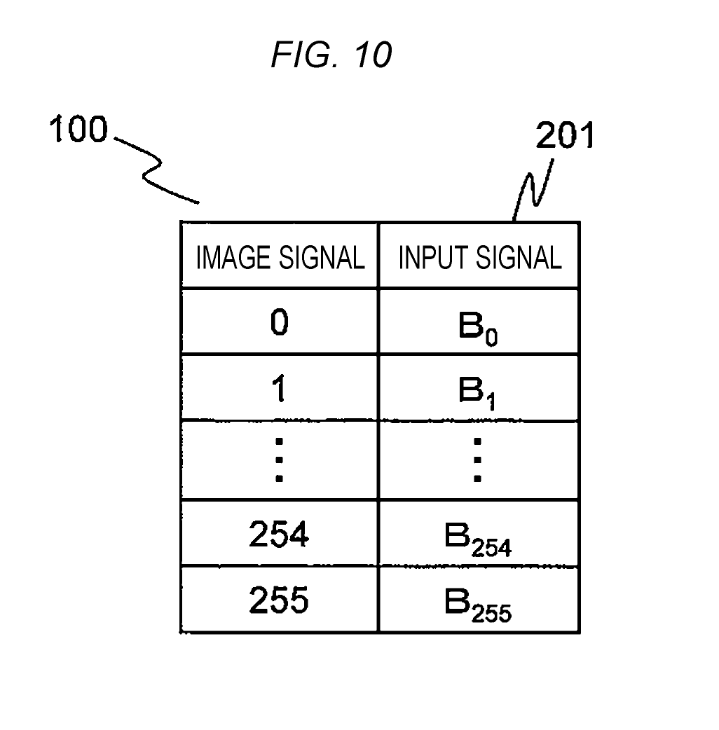

Then, an input signal B201 in each of the image signals S is calculated by the calculated approximate function B=f(S) 902, and table data 100 illustrated in FIG. 10 is created (S804).

Then, the image signal S for dimension measurement is converted into an input signal B201 according to the created table data 100 (S805).

By performing the foregoing steps, the signal of the image for dimension measurement is converted. This conversion allows the image signal for dimension measurement to be corrected in the non-linearity 203 of the output signal 202 relative to the input signal 201.

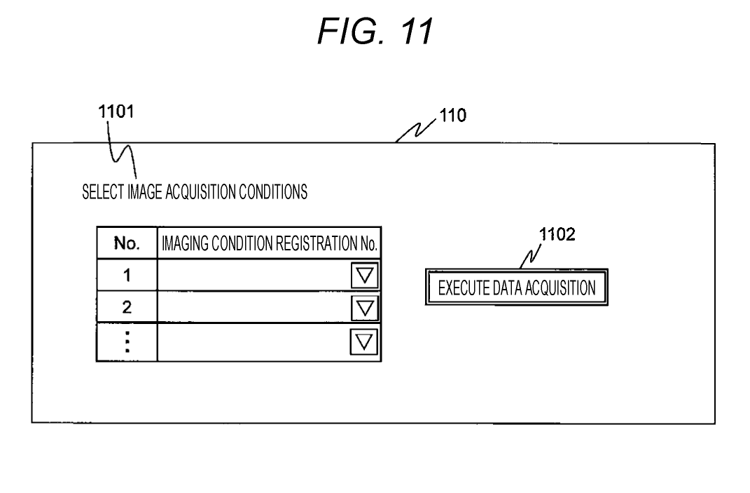

FIG. 11 illustrates an example of a GUI 110 for executing data acquisition for calculation of the signal conversion characteristics 20. The GUI includes an image acquisition condition selection field 1101 for selecting image acquisition conditions for acquiring the output signal 201 and a data acquisition execution button 1102 for executing data acquisition.

The GUI 110 is displayed on an output screen of the input/output unit 133 to allow the user to select arbitrary image acquisition conditions or confirm execution of data acquisition.

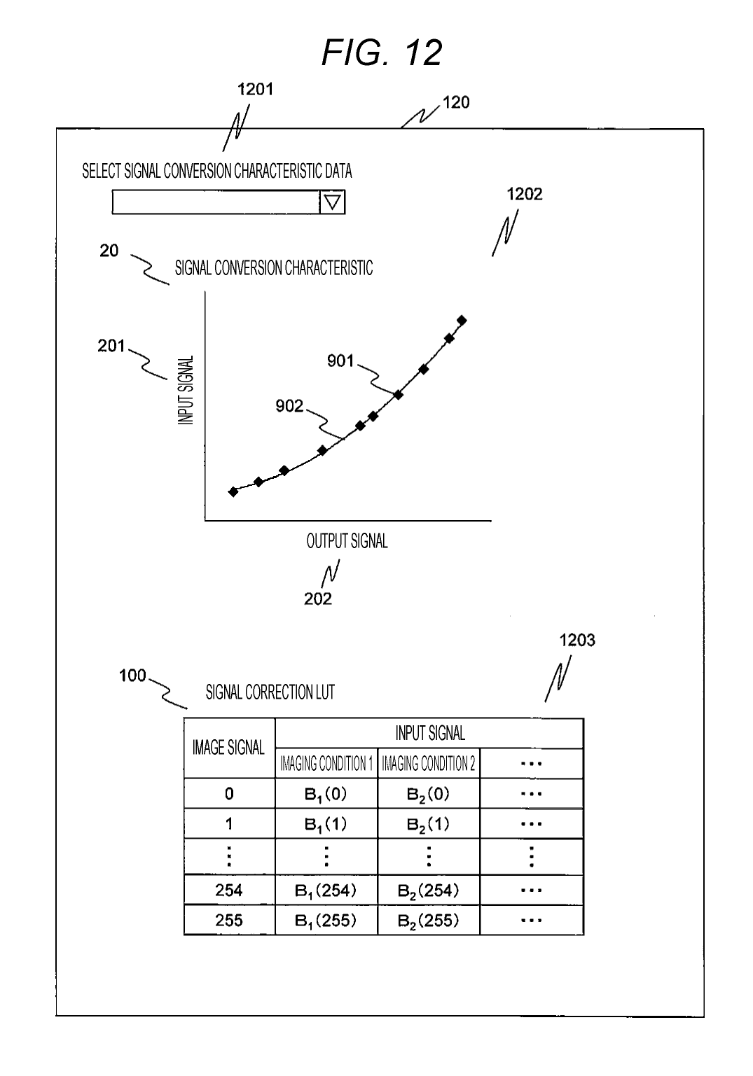

FIG. 12 illustrates an example of a GUI 120 for displaying calculation results of the signal conversion characteristics 20. The GUI 120 includes a signal conversion characteristic data selection button 1201 for selecting signal conversion characteristic data to be displayed, a display field 1202 for displaying the relationship 901 between the acquired input signal 201 and output signal 202 and the function approximation 902 of the relationship 901, and a display field 1203 for displaying the table data 100 illustrated in FIG. 10.

The corrected difference in the image signals to be measured in dimensions between the devices is smaller than that before the correction. Accordingly, the difference in results of dimension measurement using these image signals between the devices also becomes smaller. In addition, when a plurality of detectors 109 exists in one device, the difference in image signals and the difference in dimension measurement results between the detectors 109 can be reduced by executing data acquisition for calculating the signal conversion characteristics 20 described in FIG. 5 for each of the detectors 109 and performing signal conversion in the image for dimension measurement described in FIG. 8 for each of the detectors 109.

According to the scanning electron microscope system in this embodiment, it is possible to not only reduce the difference in dimension measurement results between the devices but also correct the non-linearity 203 of the output signal 202 relative to the input signal 201. Accordingly, the improvement in accuracy of dimension measurement can be expected by using library matching by which the dimensions of a target subject are measured by matching a signal waveform directly to library data of a simulation waveform, for example.

The GUI 120 is displayed on the output screen of the input/output unit 133 and allows the user to select arbitrary signal conversion characteristic data or view signal conversion characteristics and signal correction LUT.

### Embodiment 2

According to this embodiment, descriptions are hereinafter given as to another example of a flow of data acquisition for calculating the signal conversion characteristics 20 in the scanning electron microscope system described above in relation to the first embodiment with reference to FIG. 5.

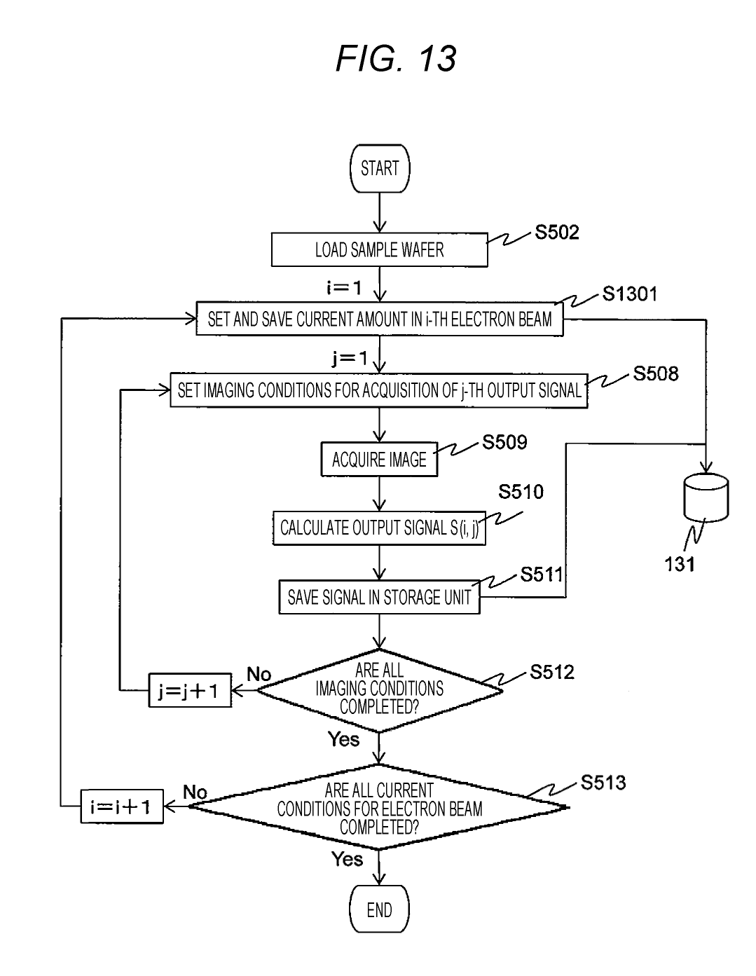

FIG. 13 illustrates an example 2 of a flow of data acquisition for calculating the signal conversion characteristics 20 in the scanning electron microscope system according to the present invention. The flow of data acquisition in this embodiment is basically the same as the flow of data acquisition for calculating the signal conversion characteristics 20 illustrated in FIG. 5, and thus descriptions are given only as to the difference from the flow of data acquisition illustrated in FIG. 5.

In the flow of FIG. 5, the image acquisition conditions without signal saturation are decided to acquire the input signal 201 at S501. The flow of FIG. 13 is different from the flow of FIG. 5 in that, since the input signal 201 is considered as being proportional to the amount of current in the electron beam 102, the amount of current in the electron beam 102 is saved as the input signal 201 in the storage unit 131 at S1301.

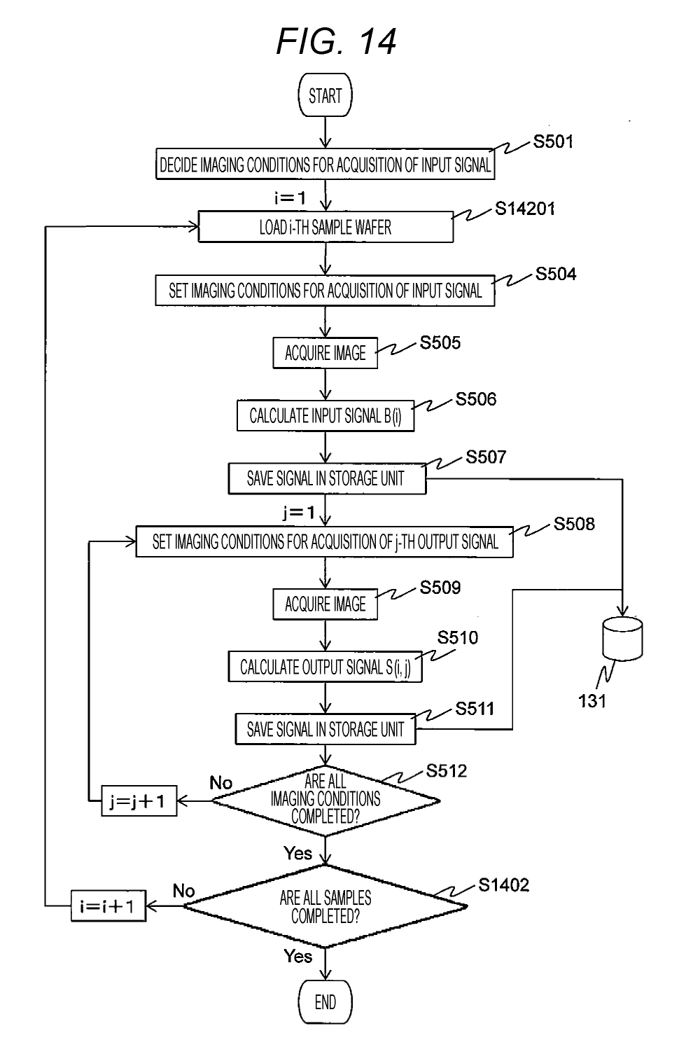

FIG. 14 illustrates an example 3 of a flow of data acquisition for calculating the signal conversion characteristics 20 in the scanning electron microscope system according to the present invention. The flow of data acquisition in this embodiment is basically the same as the flow of data acquisition for calculating the signal conversion characteristics 20 illustrated in FIG. 5, and thus descriptions are given only as to the difference from the flow of data acquisition illustrated in FIG. 5.

In the flow of FIG. 5, the magnitude of the input signal 201 is changed with variations in the amount of current in the electron beam 102 at S503. Meanwhile, in this embodiment, a plurality of samples is prepared from materials different in the yield of secondary electrons, and is used in a switched manner at 51401 and 51402 to change the magnitude of the input signal 201. Alternatively, instead of using the materials different in the yield of secondary electrons, a plurality of samples may be prepared from material different in inclination relative to the incident angle of the electron beam 102 and used in a switched manner to change the magnitude of the input signal 201. This harnesses the property of changing the yield of secondary electrons depending on the angle formed by the incident direction of the electron beam 102 and the inclination of the subject to be irradiated.

Alternatively, when the yield of secondary electrons in each of the samples or the magnitude of the input signal 201 in each of the samples is known in advance, the step of deciding imaging conditions for acquisition of the input signal 201 (S501) and the steps related to the acquisition of the input signal (S504 to S507) may be omitted to use a known input signal instead.

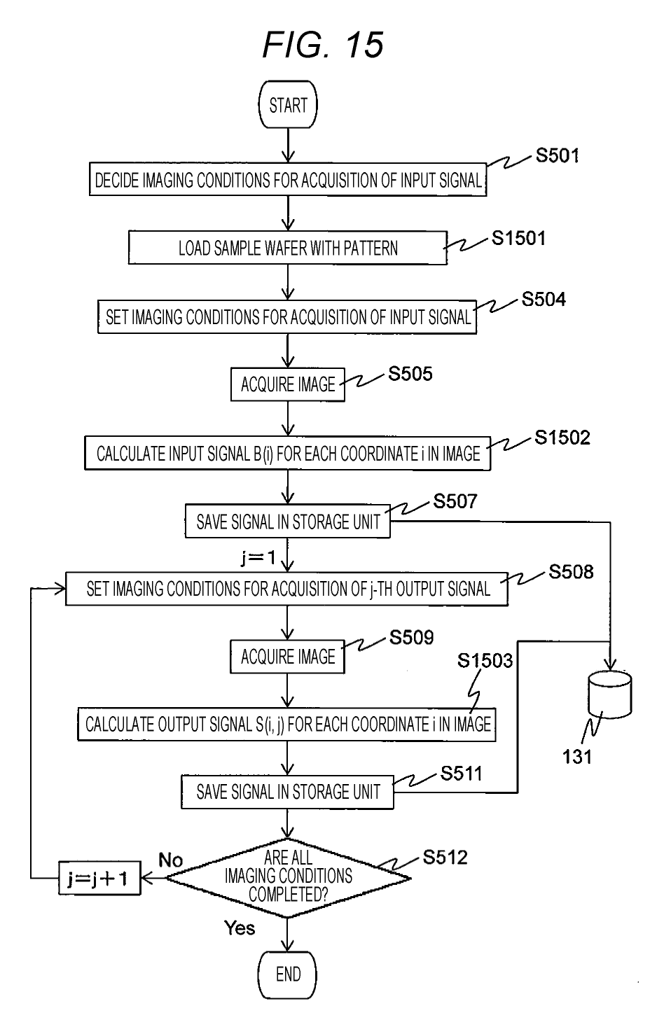

FIG. 15 illustrates an example 4 of a flow of data acquisition for calculating the signal conversion characteristics 20 in the scanning electron microscope system according to the present invention. The flow of data acquisition in this embodiment is basically the same as the flow of data acquisition for calculating the signal conversion characteristics 20 illustrated in FIG. 5, and thus descriptions are given only as to the difference from the flow of data acquisition illustrated in FIG. 5.

In the flow of FIG. 5, the magnitude of the input signal 201 is changed with variations in the amount of current in the electron beam 102 at S503. Meanwhile, in this embodiment, a sample with a pattern is used to change the magnitude of the input signal 201. As described above in relation to the example of FIG. 14, since the yield of secondary electrons varies depending on the angle formed by the incident direction of the electron beam and the inclination of the subject to be irradiated, the magnitude of the input signal 201 varies depending on the irradiated position of the pattern with asperities.

Thus, the sample wafer with a pattern is loaded at 51501, and an image with the target pattern is acquired under the imaging conditions for acquisition of the input signal at S504 and S505. Then, the input signal B(i) 201 is calculated at a position coordinate i of the acquired image at 51502. In addition, an image with the same pattern as that at S505 is acquired under the imaging conditions for acquisition of the j-th output signal 202 at S509. Then, the output signal S(i, j) 202 is calculated at the position coordinate i of the acquired image at 51503.

When the subject is imaged plural times at one and the same point, the signals vary under influence of electrical charging or the like. Thus, for acquisition of the output signal 202, it is preferred to acquire images in a pattern of a different point formed in the same manner as the target pattern in which the images are acquired at acquisition of the input signal 201. At that time, the change of imaging positions may displace the position of the pattern in the images. Thus, it is preferred that the value of the position coordinate i of the output signal 202 is corrected in alignment with the position coordinate of the input signal 201.

In each of the flows of data acquisition for calculating the signal conversion characteristics 20 in the scanning electron microscope system described above in relation to the second embodiment, the means for changing the magnitude of the input signal 201 may be combined with changing the amount of current in the electron beam 102.

### Third Embodiment

According to this embodiment, descriptions are hereinafter given as to an example of a flow of data acquisition for calculating the signal conversion characteristics 20 and an example of a flow of signal conversion of the image for dimension measurement in the scanning electron microscope system illustrated in FIG. 1, which are different from those in the first embodiment. In the first embodiment, the output signal 202 is acquired under each of the image acquisition conditions for acquisition of the image for dimension measurement. In this embodiment, taking into account the case where the data for calculating the signal conversion characteristics 20 is acquired and then the imaging conditions for acquisition of the image for dimension measurement are decided, the output signal 202 corresponding to arbitrary imaging conditions for acquisition of the image for dimension measurement is acquired to calculate the signal conversion characteristics 20.

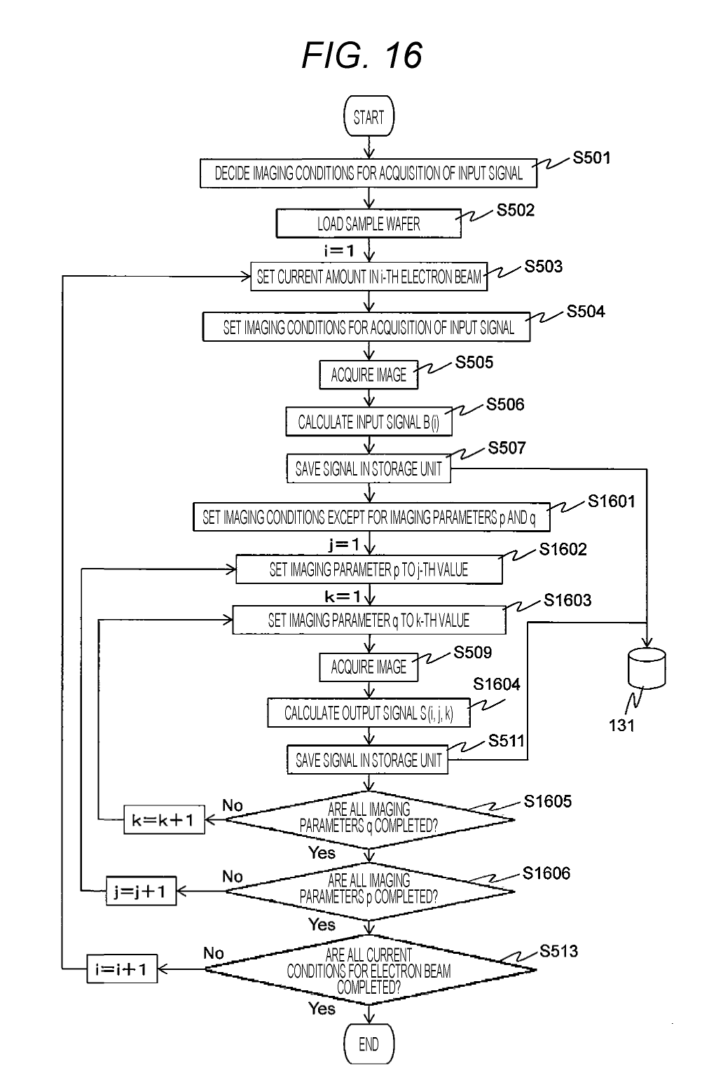

FIG. 16 illustrates an example of a flow of data acquisition for calculating the signal conversion characteristics 20 in the scanning electron microscope system according to the present invention. The flow of data acquisition in this embodiment is basically the same as the flow of data acquisition for calculating the signal conversion characteristics 20 illustrated in FIG. 5, and thus descriptions are given only as to the difference from the flow of data acquisition illustrated in FIG. 5.

At 51602 and 51603 of FIG. 16, an imaging parameter p and an imaging parameter q are set as image acquisition conditions for acquisition of the image for dimension measurement that are considered to vary depending on a subject to be measured in dimensions. Then, the image is acquired at S509. The imaging parameter p and the imaging parameter q are each set by dividing the possible setting range as appropriate. Specific examples of the imaging parameter p and the imaging parameter q are signal amplification factor, bias addition amount, and the like. The output signal calculated from the acquired image is designated as S(i, j, k).

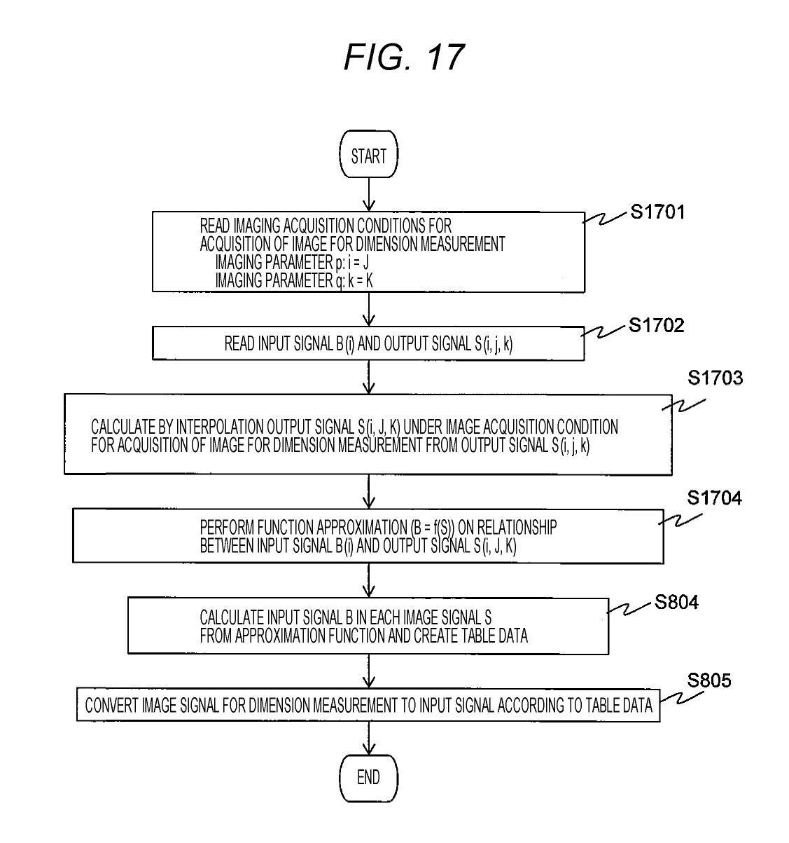

FIG. 17 illustrates a flow of signal conversion in the image for dimension measurement with the use of the data acquired in the flow of data acquisition for calculating the signal conversion characteristics 20 described in FIG. 16.

First, image acquisition conditions for acquisition of the image for dimension measurement are read (S1701). In particular, the value of the imaging parameter p is designated as P and the value of the imaging parameter q as Q.

Then, the input signal B(i) and the output signal S(i, j, k) acquired in the flow of data acquisition for calculating the signal conversion characteristics 20 are read (S1702).

Then, an output signal S(i, P, Q) is calculated by interpolation of the output signal S(i, j, k) with the imaging parameter p as P and the imaging parameter q as Q (S1703).

The subsequent steps are the same as those at S803 and subsequent steps illustrated in FIG. 8, and thus descriptions thereof are omitted.

By performing the foregoing steps, the signal of the image for dimension measurement is converted. This conversion allows the image signal of the image for dimension measurement acquired under arbitrary imaging conditions to be corrected in the non-linearity 203 of the output signal 202 relative to the input signal 201.

### Fourth Embodiment

According to this embodiment, descriptions are hereinafter given as to an example of a scanning electron microscope system configured to not only correct a difference in the signal conversion characteristics 20 between a plurality of devices but also correct temporal changes in the signal conversion characteristics 20.

In this embodiment, the scanning electron microscope system in the first to third embodiments is used to execute regularly the flow of data acquisition for calculating the signal conversion characteristics 20 and the flow of signal conversion in the image for dimension measurement with the use of the data acquired in the flow of data acquisition in the first to third embodiments. The results obtained by the regular execution are stored chronologically in the storage unit 131.

The stored signal conversion characteristics 20 are compared in chronological order, and if there is a change larger than a predetermined value, alarm display is provided.

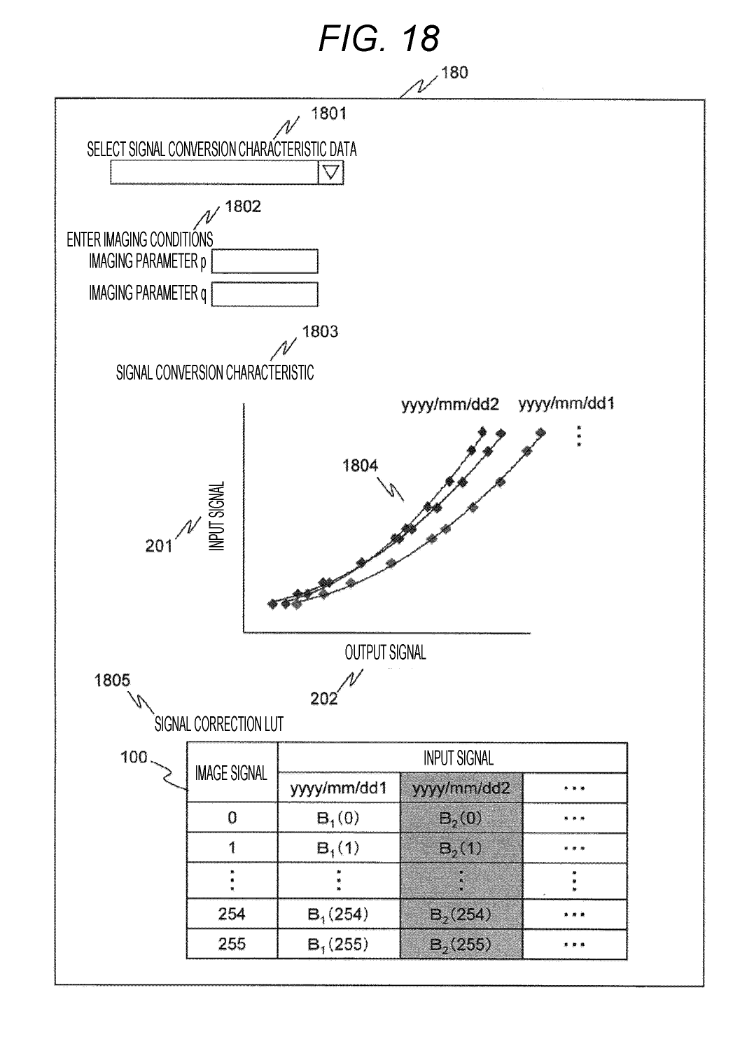

FIG. 18 illustrates an example of a GUI 180 for displaying evaluation results and temporal changes in the signal conversion characteristics 20. The GUI 180 includes a signal conversion characteristic data selection field 1801 for selecting signal conversion characteristic data to be displayed, an input field 1802 for inputting imaging conditions under which the signal conversion characteristics 20 are to be displayed, a data display field 1803 for displaying the signal conversion characteristics 20 under the input imaging conditions, a display field 1805 for displaying the table data 100 of the signal conversion characteristics 20 in chronological order, and the like. In the display field 1805 for displaying the table data 100 of the signal conversion characteristics 20 in chronological order, if there is a change in the signal conversion characteristics 20 in chronological order larger than a predetermined value, the applicable chronological data is colored to inform the user of the change. The GUI 180 is displayed on the output screen of the input/output unit 133 and allows the user to select arbitrary signal conversion characteristic data or input arbitrary imaging conditions.

### Fifth Embodiment

According to this embodiment, descriptions are hereinafter given as to an example of the scanning electron microscope system described above in relation to the first to fourth embodiments in which the scanning electron microscope main body 10 has a dedicated sample holder.

In particular, when data acquisition for calculating the signal conversion characteristics 20 is to be regularly executed as in the fourth embodiment, the data acquisition can be performed more easily by placing a permanent evaluation sample in the device than by preparing an evaluation sample at each execution of data acquisition. The scanning electron microscope main body 10 in this embodiment is configured in the same manner as that illustrated in FIG. 1. The scanning electron microscope main body 10 has on the table 108 a holder dedicated for an evaluation sample to be used in data acquisition for calculating the signal conversion characteristics 20. The evaluation sample is attached to the holder.

### Sixth Embodiment

In the first to fourth embodiments, the non-linearity 203 of the output signal 202 relative to the input signal 201 is corrected by the flow of conversion of the output signal of the image for dimension measurement. Meanwhile, according to this embodiment, descriptions are hereinafter given as to an example of correction of the non-linearity 203 of the output signal 202 relative to the input signal 201 at the time of outputting the image for dimension measurement.

In the scanning electron microscope main body 10 of FIG. 1, the signal detected by the detector 109 is processed and output as an image by the signal processing unit 11. At the signal processing unit 11, signal conversion is performed based on the calculation results of the signal conversion characteristics 20 and the imaging conditions for the image for dimension measurement saved in the storage unit 131, and then the image after the signal conversion is output. The signal conversion is performed on the PC 13 after the acquisition of the image in the first to fourth embodiments, whereas the signal conversion is performed before the output of the image in this embodiment.

### Seventh Embodiment

According to this embodiment, descriptions are hereinafter given as to an example of a scanning electron microscope system for dimension measurement configured to correct a difference between devices in non-linearity of an output signal relative to an input signal in a specific range as a reference.

An example of a configuration diagram of the scanning electron microscope in this embodiment is the same as that of FIG. 1, and thus descriptions thereof are omitted.

In this embodiment, an example 20 of the relationship 203 between the input signal 201 and the output signal 202 in a specific range (hereinafter, referred to as signal conversion characteristics) in the scanning electron microscope system illustrated in FIG. 1 is the same as that of FIG. 2, and thus descriptions thereof are omitted.

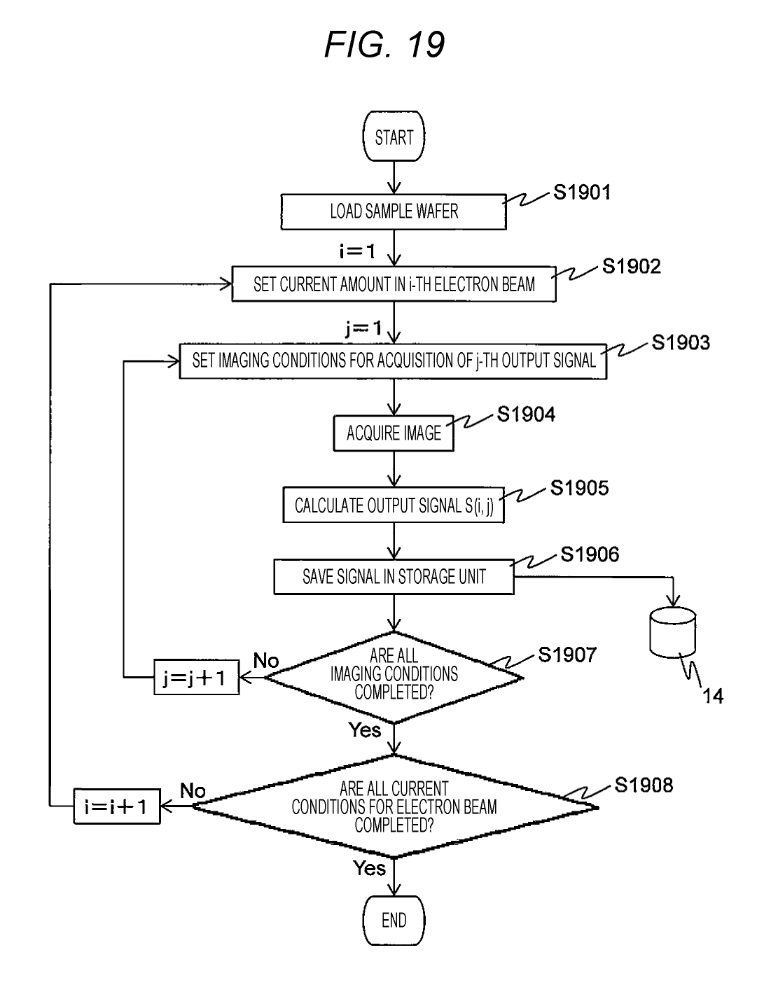

FIG. 19 illustrates a flow of data acquisition for calculating a difference in signal conversion characteristics between devices in the scanning electron microscope system illustrated in FIG. 1.

First, a sample wafer to be used in acquisition of the output signal 202 is loaded onto the table 108 of the scanning electron microscope main body 10 (S1901). In this embodiment, a solid film sample of silicon or the like without a pattern or a crystalline pattern on a wafer is used.

Then, the amount of current in the electron beam 102 as one of the image acquisition conditions is set to the i-th value (S1902). To obtain a difference in signal conversion characteristics between the devices, it is necessary to acquire the output signal 202 with a plurality of magnitudes. In this embodiment, as a means for changing the magnitude of the signal, the signal is acquired with changes in the amount of current in the electron beam 102. It is desired that the amount of current in the electron beam 102 is changed to obtain the signal in the range including the signal from the subject to be measured in dimensions.

Then, an image acquisition condition for acquiring the j-th output signal 202 except for the amount of current in the electron beam 102 is set (S1903). The image acquisition condition for acquiring the output signal 202 is set to be the same as the image acquisition condition for acquiring the image for dimension measurement. When the image for dimension measurement is to be acquired under a plurality of image acquisition conditions, the output signal 202 is acquired under each of the conditions.

Then, the image is acquired (S1904).

Then, the average value of acquired image signals with a plurality of pixels is calculated and set as an output signal S(i, j) 202 (S1905).

Then, the acquired output signal S (i, j) 202 is stored in the storage unit 14 (S1906).

The steps S1903 to S1906 are repeatedly performed until the last number j of the image acquisition condition for acquisition of the output signal 202 is reached.

In addition, the steps S1902 to S1907 are repeatedly performed until the last number i of the amount of current in the electron beam 102 is reached (S1908).

After the execution of the foregoing steps, the data acquisition of the output signal S(i, j) 202 with the amount of current i in the electron beam 102 is terminated.

The data acquisition for calculating a difference in signal conversion characteristics between devices in the flow of FIG. 19 is performed at a plurality of devices to be corrected in the difference, and then the results obtained by the devices are stored together with device identification information in the storage unit 14.

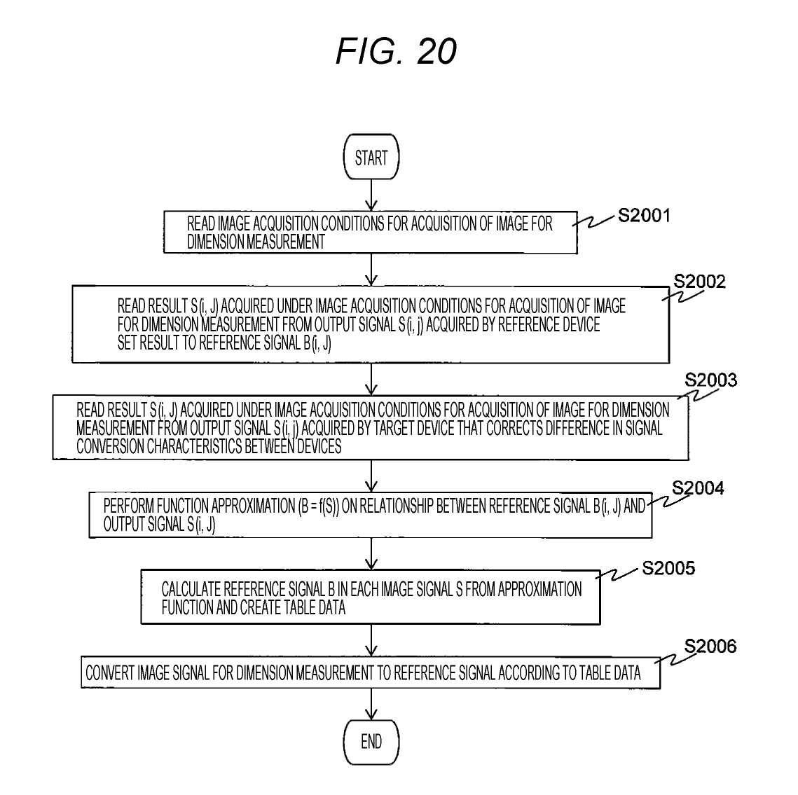

FIG. 20 illustrates a flow of signal conversion in the image for dimension measurement, with the use of the data for calculating the signal conversion characteristics of the plurality of devices that is acquired in the flow of data acquisition for calculating the signal conversion characteristics described in FIG. 19.

First, the image acquisition conditions for acquiring the image for dimension measurement acquired at the devices to be corrected in the difference of signal conversion characteristics between the devices are read (S2001).

Then, of the output signals S(i, j) 202 acquired in the flow of data acquisition for calculating the signal conversion characteristics, the output signal S(i, j) 202 acquired under a target image acquisition condition (i=J) is read into a reference device. The read result is set as a reference signal B(i, J) (S2002).

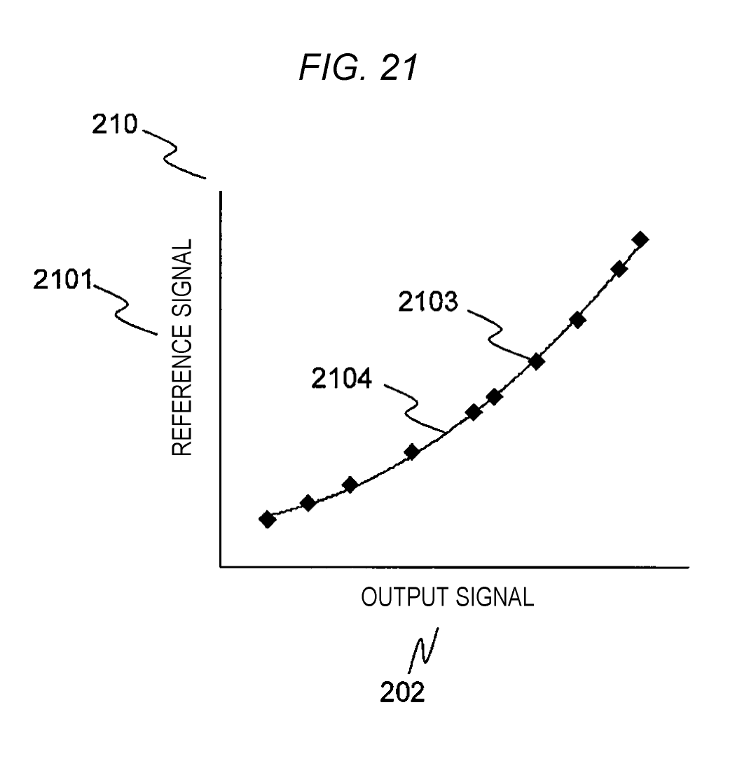

Then, of the output signals S(i, j) 202 acquired in the flow of data acquisition for calculating the signal conversion characteristics, the output signal S(i, j) 202 acquired under the target image acquisition condition (i=J) is read into the devices to be corrected in the difference of signal conversion characteristics between the devices. The read result is set as a reference signal S (i, J) (S2003). FIG. 21 illustrates a relationship 2103 between the reference signal B(i, J) 2101 and the output signal S(i, J) 202 of the devices to be corrected in the difference of signal conversion characteristics between the devices.

Then, the relationship illustrated in FIG. 21 is approximated by the function B=f(S) (S2004). FIG. 21 illustrates an experimentally acquired example of a difference in signal conversion characteristics between the devices in the scanning electron microscope system. The function for use in the approximation may be a sigmoid function or a quadratic function, for example. FIG. 21 also illustrates an approximate function 2104.

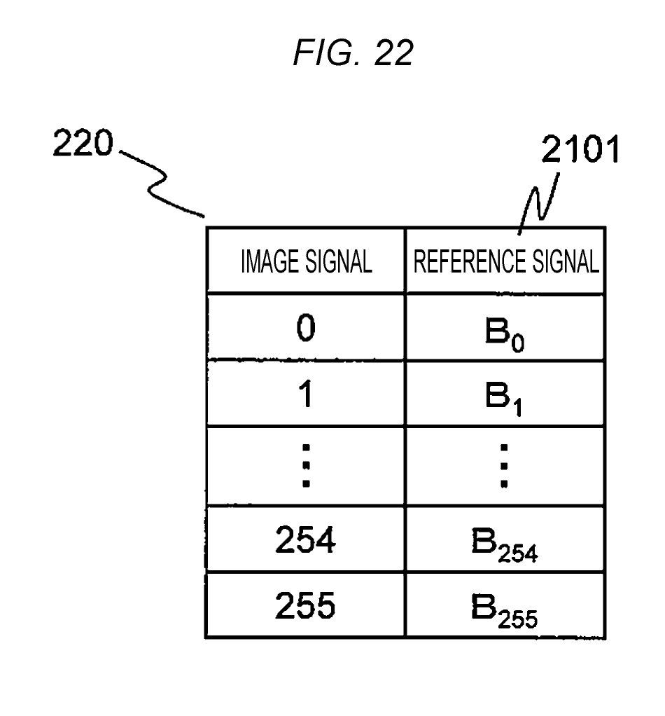

Then, a reference signal B2101 is calculated for each of the output signals S from the calculated approximate function B=f(S), and table data 220 is created as illustrated in FIG. 22 (S2005). FIG. 22 illustrates an example of a table of image signals in the reference device corresponding to image signals in an evaluation device according to the present invention.

Then, the image signal S for dimension measurement acquired at the devices to be corrected in difference of signal conversion characteristics between the devices is converted into the reference signal B2101 according to the created table data 220 (S2006).

By performing the foregoing steps, the signal of the image for dimension measurement acquired at the devices to be corrected in difference of signal conversion characteristics between the devices is converted. According to this conversion, the image signal 202 for dimension measurement acquired at the devices to be corrected in difference of signal conversion characteristics between the devices, can be corrected in non-linearity 2103 of the output signal 2101 of the reference device.

An example of a GUI necessary for data acquisition for calculating a difference in signal conversion characteristics between the devices is the same as that illustrated in FIG. 11, and thus descriptions thereof are omitted.

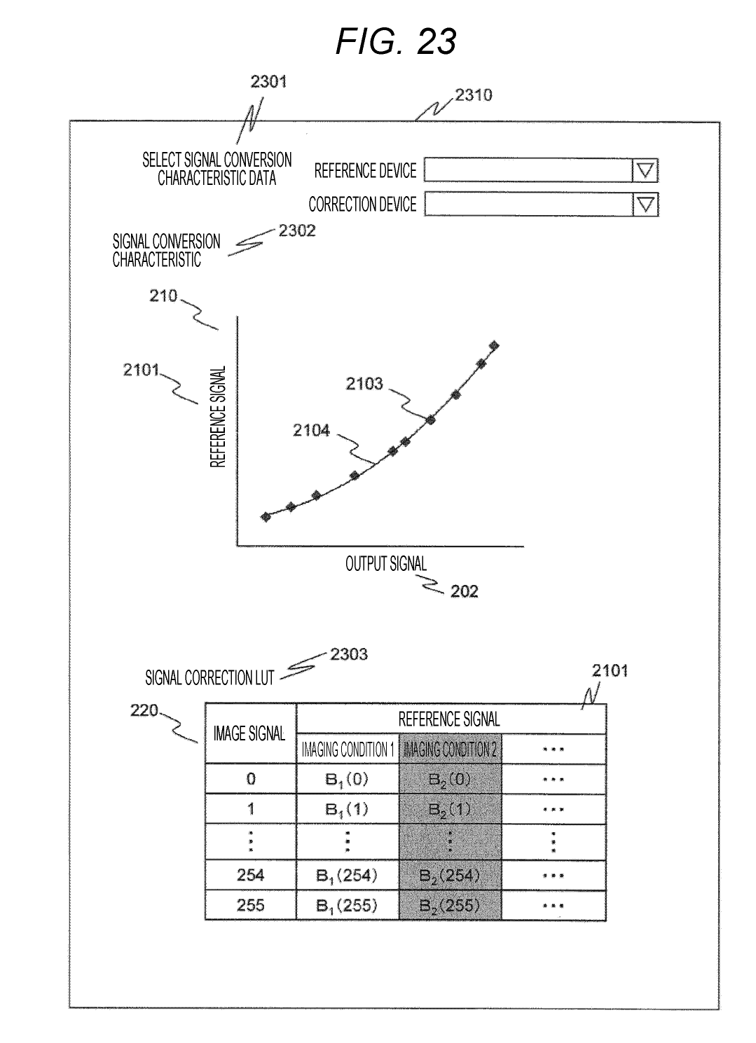

FIG. 23 illustrates an example of a GUI 230 for displaying calculation results of the difference in signal conversion characteristics between the devices. The GUI 230 includes a selection field 2301 for selecting signal conversion characteristic data to be displayed, a field 2302 for illustrating the relationship 2103 between the reference signal 2101 and the output signal 202 from the devices to be corrected in difference of signal conversion characteristics between the devices and a result 2104 obtained by subjecting the relationship 2103 to function approximation, and a display field 2303 for displaying the table data 220 illustrated in FIG. 22.

The corrected difference in the image signals to be measured in dimensions between the devices is smaller than that before the correction. Accordingly, the difference in results of dimension measurement using these image signals between the devices also becomes smaller. In addition, when a plurality of detectors 109 exists in one device, the difference in image signals and the difference in dimension measurement results between the detectors 109 can be reduced by executing data acquisition for calculating the signal conversion characteristics described in FIG. 19 for each of the detectors 109 and performing signal conversion in the image for dimension measurement described in FIG. 20 for each of the detectors 109.

The GUI 110 is displayed on an output screen of the input/output unit 133 to allow the user to select arbitrary image acquisition conditions or confirm execution of data acquisition.

### Eighth Embodiment

The second to sixth embodiments as modification examples of the first embodiment are also applicable to the seventh embodiment.

### Ninth Embodiment

According to this embodiment, descriptions are hereinafter given as to an example of a system for correcting the non-linearity 203 of the output signal 202 relative to the input signal 201 and a difference 1904 between the devices, which is connected to the scanning electron microscope main body 10, the signal processing unit 11, and the general control unit 12.

The configuration of the system is equivalent to the PC 13 illustrated in FIG. 1, and can be realized by connecting the PC 13 to the scanning electron microscope system.

The contents of the processes performed in the system are as described above in relation to the first to eighth embodiments, and thus detailed descriptions thereof are omitted.

### Tenth Embodiment

In this embodiment, descriptions are hereinafter given as to an example of an execution program for correcting the non-linearity 203 of the output signal 202 relative to the input signal 201 and the difference 1904 between the devices, which is installed in the PC 13 connected to the scanning electron microscope main body 10.

The contents of the processes performed in the system are as described above in relation to the first to eighth embodiments, and thus detailed descriptions thereof are omitted.

### Eleventh Embodiment

Each of the first to tenth embodiments is limited to a scanning electron microscope device for dimension measurement. However, the scanning electron microscope device is not necessarily to be used in dimension measurement as far as it is a device, a system, or a program configured in the same manner. In addition, the present invention is not limited to a scanning electron microscope device but may be applied to a transmission electron microscope device or another charged particle microscope device.

As described above, according to the present invention, it is possible to provide the function of correcting a difference in signal amount between devices by which to quantitatively evaluate output signals (image quality) acquired from the devices relative to an input signal in a specific range as a reference, and use the evaluation results to adjust the output signals from the devices to be equivalent in magnitude.

The present invention is applicable to a charged particle microscope system and a measurement method using the same.

### REFERENCE SIGNS LIST

10 scanning electron microscope main body
101 electron gun
102 electron beam
103 acceleration electrode
104 focusing lens
105 deflection electrode
107 sample
106 objective lens
108 table
109 detection unit 109
12 general control unit 12

1. A charged particle microscope system, comprising:
a charged particle microscope including an irradiation unit that irradiates a subject to be inspected with a charged particle beam and a detection unit having a detector that detects a charged particle signal from the subject to be inspected irradiated by the irradiation unit;
a signal processing unit that converts the charged particle signal detected by the detector of the charged particle microscope into an image signal; and
an arithmetic processing unit that corrects the image signal converted by the signal processing unit with the use of signal conversion characteristics.

2. The charged particle microscope system according to claim 1, wherein the signal conversion characteristics constitute a relationship between the charged particle signal input into the signal processing unit and the image signal output from the signal processing unit.

3. The charged particle microscope system according to claim 1, wherein, at the arithmetic processing unit, the predetermined relationship between the input signal as the charged particle signal and the output signal as the image signal is used to correct the image signal converted at the signal processing unit.

4. The charged particle microscope system according to claim 3, wherein, when the detection unit includes a plurality of detectors, each of the plurality of detectors has the predetermined relationship between the input signal and the output signal.

5. The charged particle microscope system according to claim 1, wherein, at the arithmetic processing unit, a plurality of pieces of image data acquired by imaging under a first imaging condition included in a plurality of imaging conditions is processed to acquire a plurality of input signals, and a plurality of pieces of image data acquired by imaging a second imaging condition different from the first imaging condition is processed to acquire an output signal, thereby to acquire the signal conversion characteristics.

6. The charged particle microscope system according to claim 1, wherein the plurality of imaging conditions includes at least one of the amount of current in the charged particle beam to be applied to the subject to be inspected, the material for the subject to be inspected, and the inclination of the subject to be inspected.

7. The charged particle microscope system according to claim 1, further comprising a display unit that displays the signal conversion characteristics calculated at the arithmetic processing unit.

8. The charged particle microscope system according to claim 1, wherein, at the arithmetic processing unit, the signal conversion characteristics are used to convert the output signal from the signal processing unit into the size of the signal detected by the detectors.

9. The charged particle microscope system according to claim 1, further comprising a storage unit that stores the signal conversion characteristics.

10. A measurement method using a charged particle microscope system, comprising:
the measurement step of the charged particle microscope system including the irradiation step of irradiating a subject to be inspected with a charged particle beam and the detection step of detecting a charged particle signal from the subject to be inspected irradiated at the irradiation step;
the signal processing step of converting the charged particle signal detected at the detection step into an image signal; and
the arithmetic processing step of correcting the image signal converted at the signal processing step with the use of signal conversion characteristics.

11. The measurement method using a charged particle microscope system according to claim 10, wherein the signal conversion characteristics constitute a relationship between the charged particle signal detected at the signal processing step and the image signal output at the signal processing step.

12. The measurement method using a charged particle microscope system according to claim 10, wherein, at the arithmetic processing unit, the predetermined relationship between the input signal as the charged particle signal and the output signal as the image signal is used to correct the image signal converted at the signal processing step.

13. The measurement method using a charged particle microscope system according to claim 12, wherein, when the charged particle signal is detected by a plurality of detectors at the detection step, each of the plurality of detectors has the predetermined relationship between the input signal and the output signal.

14. The measurement method using a charged particle microscope system according to claim 10, wherein, at the arithmetic processing step, a plurality of pieces of image data acquired by imaging under a plurality of imaging conditions is processed to acquire a plurality of input signals, and a plurality of pieces of image data acquired by imaging the plurality of imaging conditions is processed to acquire an output signal, thereby to acquire the signal conversion characteristics.

15. The measurement method using a charged particle microscope system according to claim 10, wherein the plurality of imaging conditions includes at least one of the amount of current in the charged particle beam to be applied to the subject to be inspected, the material for the subject to be inspected, and the inclination of the subject to be inspected.

16. The measurement method using a charged particle microscope system according to claim 10, further comprising the display step of displaying the signal conversion characteristics calculated at the arithmetic processing step.

17. The measurement method using a charged particle microscope system according to claim 10, wherein, at the arithmetic processing step, the signal conversion characteristics are used to convert the output signal output at the signal processing step into the size of the signal detected at the detection step.

18. The measurement method using a charged particle microscope system according to claim 10, further comprising the storage step of storing the signal conversion characteristics.
